(19) United States
(12) Patent Application Publication
(10) Pub. No.: US 2015/0037927 A1
(43) Pub. Date: Feb. 5, 2015

(54) METHOD FOR PRODUCING THE PENTANARY COMPOUND SEMICONDUCTOR CZTSSE DOPED WITH SODIUM

(71) Applicant: SAINT-GOBAIN GLASS FRANCE, COURBEVOIE (FR)

(72) Inventors: Robert Lechner, Muenchen (DE); Gowtham Manoharan, Bourg La Reine (FR); Stefan Jost, Muenchen (DE)

(21) Appl. No.: 14/380,169

(22) PCT Filed: Apr. 25, 2013
(86) PCT No.: PCT/EP2013/058670

§ 371 Date: Aug. 21, 2014

(30) Foreign Application Priority Data
Apr. 27, 2012 (EP) 12166090.6

(51) Int. Cl. H01L 31/18

(52) U.S. Cl. CPC H01L 31/1832; H01L 31/1864
USPC 438/95

(57) ABSTRACT

A method for producing a layered stack for manufacturing a thin film solar cell having a compound semiconductor of the type Cu₂ZnSn(S,Se)₄ is described. The method has the steps of: providing a substrate; depositing a barrier layer consisting of a material adapted to inhibit the diffusion of alkali metals on said substrate; depositing an electrode layer on said barrier layer; depositing a first precursor layer comprising the metals copper, zinc and tin; depositing a second precursor layer comprising at least one chalcogene selected from sulphur and selenium on said first precursor layer; annealing said precursor layers to crystallize said compound semiconductor; supplying at least one process gas during annealing of said first and second precursor layers; and depositing elemental sodium and/or a sodium containing compound on the precursor layers and/or the electrode layer in advance of the annealing of the precursor layers, on the precursor layers during said annealing of the precursor layers, and/or on said compound semiconductor.

### TECHNICAL FIELD

The present invention is in the field of manufacturing thin film solar cells and specifically relates to a method for producing a layered stack for manufacturing a thin film solar cell comprising an absorber made of a sodium-doped pentanary compound semiconductor of the type CZTSSe.

### BACKGROUND OF THE INVENTION

In recent years, an increased use of solar cells for converting solar light into electric energy can be observed. Due to a cost-efficient production process combined with comparably high conversion efficiency a special interest can be seen in thin film solar cells. Thin film solar cells have functional layers as thin as some micrometers and, thus, require substrates such as glass plates, metal plates or plastic foils to attain sufficient mechanical stability.

Thin film solar cells based on polycrystalline compound semiconductors of the type Cu (In, Ga) (S,Se)₂ have proven advantageous in view of their processability and conversion efficiency. In order to further reduce the production costs and in view of the long-term availability of the materials concerned, strong efforts have been made to find alternatives to the Cu (In, Ga) (S, Se)₂-based compound semiconductors. In these days, a promising alternative is seen in pentanary semi-conductors of the type Cu₂ZnSn (S, Se)₄ consisting of copper (Cu), zinc (Zn), tin (Sn), sulphur (S) and selenium (Se) usually abbreviated by the acronyme “CZTSSe”. In visible light, semiconductor thin films based on CZTSSe typically have absorption coefficients as high as 10⁴ cm⁻¹ and a direct band gap of about 1.5 eV.

Generally, the specific properties of the light absorbing material of thin film solar cells are decisive for the efficiency of light conversion. Two different methods for producing the absorber have achieved broad acceptance, one method being the co-evaporation of the elemental substances on a hot substrate, the second one being a successive deposition of the precursor materials on a cold substrate followed by an annealing process (RTP=Rapid Thermal Processing) causing the precursor materials to crystallize to the compound semiconductor. Such method, e.g., is described in J. Palm et al., “CIS module pilot processing applying concurrent rapid selenization and sulfurization of large area thin film precursors”, Thin Solid Films 431-432, S. 414-522 (2003).

US patent application publication No. 2007/0193623 A1 describes the deposition of sodium on the back electrode of a solar cell having a light absorbing material made of CIGS. It further describes the supply of sodium during the thermal treatment of the light absorbing material applied as solution and the deposition of sodium after the thermal treatment of the light absorbing material onto a cooled substrate.

German patent DE 4442824 C1 describes the deposition of sodium on the back electrode of a solar cell as well as co-sputtering of sodium together with precursor materials of the light-absorbing material made of CIGS.

International patent application WO 2011/090728 A2 describes the co-deposition of sodium with the light-absorbing material.

In light of the foregoing, it is an object of the invention to provide a new method for producing layered stacks for manufacturing thin film solar cells which can readily be used to improve the light conversion efficiency of thin film solar cells. These and further objects are met by a method according to the independent claim. Preferred embodiments of the invention are given by the dependent claims.

### SUMMARY OF THE INVENTION

As used herein, the term “substrate” denotes any planar body having two opposing surfaces onto one of which a sequence of layers can be deposited. Substrates in the sense of the term include stiff or flexible substrates, such as, but not limited to, glass plates, metal sheets, plastic sheets and plastic foils. The term “compound semiconductor” denotes any semiconducting material (alloy) consisting of a plurality of metals and chalcogens (precursor materials) crystallized with each other to yield the compound semiconductor. Accordingly, precursor materials are substances which upon crystallization yield the compound semiconductor. The term “precursor layer” relates to a layer made of at least one precursor material. The term “sequence” relates to a stacked arrangement of layers. Furthermore, as used herein, the term physical vapour deposition technique (PVD-technique) relates to a technique in which a solid or liquid material is transformed into its gas phase by supplying energy to then be condensed on a surface. As used herein, the terms “first boundary face” and “second boundary face” relate to boundary faces of the compound semiconductor, with the first boundary face being more distanced from the substrate than the second boundary face. Consequently, the first boundary face is closer to the surface of the layered stack and solar cell, respectively, than the second boundary face.

According to the invention, a new method for producing a layered stack for manufacturing a thin film solar cell having an absorber consisting of a compound semiconductor is proposed.

In one embodiment, the claimed process is related to the manufacturing of a thin film solar cell having an absorber consisting of a compound semiconductor of the type Cu₂ZnSn(S,Se)₄, abbreviated CZTSSe. Accordingly, the compound semiconductor contains copper (Cu), zinc (Zn), tin (Sn), sulphur (S) and selenium (Se). The compound semiconductor Cu₂ZnSn(S,Se)₄ may exhibit off-stoichiometric behaviour meaning that Cu/(Zn+Sn)<1 and Zn/Sn>1. Values for Cu/(Zn+Sn) may range between 0.4 and 1 and Zn/Sn may range between 0.5 and 2.0.

In one embodiment, the method comprises a step of providing of a substrate.

In one embodiment, the method comprises a step of depositing of a barrier layer on said substrate made of a material adapted to inhibit the diffusion of alkaline metals, in particular sodium ions.

In one embodiment, the method comprises a step of depositing of an electrode layer on the barrier layer made of an electrically conductive material. Accordingly, diffusion of alkaline metals, in particular sodium ions, between the substrate and the electrode layer can be inhibited by the barrier layer.

In one embodiment, the method comprises a step of depositing of precursor layers on the electrode layer, each of which consisting of at least one precursor material of a compound semiconductor, followed by a further step of annealing (thermal-processing) the precursor layers to crystallize the compound semiconductor (annealing process).

In one embodiment, the above-described step of depositing precursor layers comprises
depositing of a first precursor layer comprising the metals copper, zinc and tin;
depositing of a second precursor layer comprising at least one chalcogen selected from sulphur and selenium on the first precursor layer;
supplying at least one process gas during annealing (thermal-processing) of the first and second precursor layers, wherein

(i) in case either sulphur or (alternatively) selenium is contained in the second precursor layer, the other chalcogen and/or an compound containing the other chalcogen is contained in the process gas, or

(ii) in case both sulphur and selenium are contained in the second precursor layer, sulphur and/or selenium and/or a compound containing sulphur and/or a compound containing selenium is contained in the process gas.

As above-described, by depositing the precursor materials in a two-stage process, the compound semiconductor can be readily produced and exhibits excellent electronic properties. Furthermore, the sulphur depth profile can be adjusted in highly controlled manner.

In one embodiment, the method comprises a step of depositing of elemental sodium and/or a sodium-containing compound on the electrode layer and/or a step of depositing of elemental sodium and/or a sodium-containing compound on the precursor layers prior to the annealing process of the precursor layers. In one embodiment, elemental sodium and/or a sodium-containing compound can be deposited on top of the precursor layers. Otherwise, in one embodiment, the elemental sodium and/or a sodium-containing compound can be deposited in-between the precursor layers.

In one embodiment, the method comprises a step of depositing of elemental sodium and/or a sodium-containing compound on the precursor layers during the annealing process of the precursor layers. Preferably, in one embodiment, gaseous sodium and/or a gaseous sodium-containing compound is produced by thermal evaporation of one or more source materials and is supplied during annealing of the precursor layers as a reaction gas. As a result, an especially pure semiconductor can be obtained in a highly time and cost efficient manner. Specifically, compared to the known process of applying a sodium solution onto the absorber material, the introduction of solvent into the absorber material can advantageously be avoided. Furthermore, due to the fact that any wet-chemical process usually causes high costs (e.g. for the disposal of waste), costs for fabricating solar cells can advantageously be reduced by applying sodium as reaction gas.

In one embodiment, the method comprises a step of depositing of elemental sodium and/or a sodium-containing compound on the yet crystallized compound semiconductor after the annealing process of the precursor layers.

In one embodiment, the compound semiconductor is produced in such a manner that one of the following sodium depth profiles between the first boundary face and the second boundary face of the compound semiconductor is obtained:

(i) a sodium content at the first boundary face is maximal and continuously decreases towards the second boundary face to be minimal at the second boundary face,

(ii) a sodium content at the first boundary face is minimal and continuously increases towards the second boundary face to be maximal at the second boundary face,

(iii) a sodium content at the first boundary face has a first maximum, decreases towards the second boundary face to have a minimum, and then increases towards the second boundary face to have a second maximum at the second boundary face,

(iv) a sodium content at the first boundary face has a first minimum, increases towards the second boundary face to have a maximum, and then decreases towards the second boundary face to have a second minimum at the second boundary face.

Accordingly, the compound semiconductor can have various definite and highly-controlled sodium depth profiles according to the specific demands of the user so as to specifically adapt the electronic properties of the compound semiconductor to the desired use cases.

In one embodiment, the compound semiconductor is produced in such a manner that one of the following sulphur depth profiles between the first boundary face and the second boundary face of the compound semiconductor is obtained:

(i) a sulphur content at the first boundary face is maximal and continuously decreases towards the second boundary face to be minimal at the second boundary face,

(ii) a sulphur content at the first boundary face is minimal and continuously increases towards the second boundary face to be maximal at the second boundary face,

(iii) a sulphur content at the first boundary face has a first maximum, decreases towards the second boundary face to have a minimum, and increases towards the second boundary face to have a second maximum at the second boundary face,

(iv) a sulphur content at the first boundary face has a first minimum, increases towards the second boundary face to have a maximum, and decreases towards the second boundary face to have a second minimum at the second boundary face.

Accordingly, the compound semiconductor can have various definite and highly-controlled sulphur depth profiles according to the specific demands of the user so as to specifically adapt the electronic properties of the compound semiconductor to the desired use cases.

In the pentanary semiconductor CZTSSe as described here, a variation of the sulphur content over the depth of the semi-conductor means a variation of the bandgap over the thickness of the semiconductor. It, thus, is possible to obtain a bandgap thickness profile in the CZTSSe thin film by exchanging selenium and sulphur in CZTSSe. As a result, it is possible to specifically adapt the electronic properties of the compound semiconductor to the desired use cases.

In one embodiment, the compound semiconductor is produced in such a manner that a relative change of the sulphur content along the sulphur depth profile amounts to at least 10%. As a result, a comparably large difference of the band gap across the thickness of the semiconductor can be realized so as to obtain favourable effects with respect to power loss and light conversion efficiency of the fabricated solar cell.

Generally, any of the above-described sodium profiles (i) to (iv) can be combined with any of the above-described sulphur profiles (i) to (iv) in order to optimize the light conversion efficiency of the fabricated solar cell. Accordingly, in case the compound semiconductor has one of the above-described sulphur depth profiles denoted by (i) to (iv), a sodium depth profile denoted by the same or any other number (i) to (iv) may be present.

In one embodiment, the compound semiconductor is produced in such a manner that it has the following sodium depth profile: a sodium content at the first boundary face has a first maximum, decreases towards the second boundary face to have a minimum, and then increases towards the second boundary face to have a second maximum at the second boundary face, and that it has the following sulphur depth profile: a sulphur content at the first boundary face has a first maximum, decreases towards the second boundary face to have a minimum, and increases towards the second boundary face to have a second maximum at the second boundary face.

Accordingly, due to the lower sulphur content in the inner region of the semiconductor sandwiched in-between the two boundary faces resulting in a lower band gap, the absorption rate of the solar cell can advantageously be increased due to the fact that low-energetic light can also be exploited. Hence, the light conversion efficiency of the solar cell can be increased. Furthermore, due to the higher sulphur content at the first boundary face of the semiconductor yielding a higher band gap compared to the inner region, an off-load voltage of the solar cell can advantageously be increased so as to further increase the light conversion efficiency of the solar cell. Moreover, due to the higher sulphur content at the second boundary face of the semiconductor resulting in a higher band gap compared to the inner region, an undesired power loss of the solar cell caused by recombinations of charge carriers can advantageously be reduced so as to yet further increase the light conversion efficiency of the solar cell. Accordingly, this sulphur depth profile results in an especially high light conversion efficiency of the solar cell.

Further, due to the higher sodium content at the first and second boundary faces, the compound semiconductor can be produced with an especially high crystal quality at the boundary faces since sodium is able to favourably influence the crystal formation. As a result, the above-described physical effects with respect to increasing the light conversion efficiency of the solar cells can further be improved by having a sodium depth profile similar to the sulphur depth profile. Accordingly, solar cells having a particularly low power loss and high light conversion efficiency can advantageously be obtained. This especially applies to pentanary absorber materials consisting of a compound semi-conductor of the type Cu₂ZnSn(S,Se)₄ produced in a two-stage process so that the compound semiconductor exhibits excellent electronic properties by exactly controlling the sulphur and sodium depth profiles. Accordingly, the above-described synergistic effect of sodium and sulphur depth profiles can be obtained with pentanary absorber materials of the type Cu₂ZnSn(S,Se)₄.

In order to obtain such a sodium depth profile, in one embodiment, the method comprises a step of depositing of elemental sodium and/or a sodium-containing compound on said electrode layer and a step of depositing of elemental sodium and/or a sodium-containing compound on top of the precursor layers, e.g. in advance of the annealing of the precursor layers. As a result, the sodium content at the first and second boundary faces can readily be increased with respect to the inner region of the compound semiconductor, with the desired sodium and sulphur depth profiles being producible in highly cost and time efficient manner.

Accordingly, the method of the invention allows the production of thin film solar cells having an improved efficiency for converting light into electric energy. The dopant sodium can be readily deposited prior and/or during and/or after the annealing process of the precursor materials. Stated more particularly, the dopant sodium can be deposited only prior to the annealing process or only during the annealing process or only after the annealing process or both prior to and during the annealing process or both prior to and after the annealing process or both during and after the annealing process or both prior to, during and after the annealing process. According to the specific deposition process used, a dedicated sodium depth profile of the compound semi-conductor can readily be obtained so as to specifically adapt the electronic properties of the compound semiconductor to the demands of the user.

In one embodiment, the step of depositing of elemental sodium and/or a sodium-containing compound on the compound semiconductor after the annealing process of the precursor layers is followed by a step of thermal-processing the compound semi-conductor for chemically activating sodium as dopant in the compound semiconductor. Accordingly, the conversion efficiency of the solar cell can readily be improved.

Preferably, in one embodiment, for activating the dopant, the compound semiconductor is heated to a temperature lower than a temperature for heating the precursor layers for annealing of the precursor materials so as to crystallize the compound semi-conductor. In one embodiment, the compound semiconductor is heated to a temperature in a range of from 100° C. to 400° C. In one embodiment, the compound semiconductor is heated to a temperature in a range of from 100° C. to 300° C. In one embodiment, the compound semiconductor is heated to a temperature in a range of from 100° C. to 200° C. Hence, solar cells can be manufactured in a highly cost-efficient manner, with the cost-efficiency being increased the lower the temperature is.

In one embodiment, elemental sodium and/or a sodium-containing compound is deposited on the yet hot compound semiconductor after annealing of the precursor layers. Specifically, sodium is deposited in such a manner that as a result of annealing of the precursor layers during deposition of sodium the compound semiconductor yet has a temperature sufficiently high for chemically activating sodium as dopant in the compound semi-conductor. In one embodiment, when starting deposition of the sodium and/or sodium-containing compound, the compound semi-conductor has a temperature in a range of from 100° C. to 400° C. In one embodiment, when starting deposition of the sodium and/or sodium-containing compound, the compound semiconductor has a temperature in a range of from 100° C. to 300° C. In one embodiment, when starting deposition of the sodium and/or sodium-containing compound, the compound semiconductor has a temperature in a range of from 100° C. to 200° C.

Hence, the compound semiconductor can be doped in a highly time and cost efficient manner. Preferably, the crystallized compound semiconductor is made to pass a source of elemental sodium and/or a sodium-containing compound so as to deposit sodium on the compound semiconductor yet hot due to the annealing process so as to readily deposit elemental sodium and/or a sodium-containing compound in a particularly high cost- and time-efficient manner.

In one embodiment, the compound semiconductor is produced in such a manner that a mass fraction of sodium in the compound semiconductor, relative to a mass fraction of the metals copper, zinc and tin contained in the compound semiconductor, is in a range of from 0.01% and 0.5% so as to yield a particularly high conversion efficiency.

The above-described various embodiments of the method for producing a layered stack for manufacturing a thin film solar cell according to the invention can be used alone or in any combination thereof without departing from the scope of the invention.

The invention further relates to a method for manufacturing thin film solar cells comprising the above-described method for producing a layered stack.

### BRIEF DESCRIPTION OF THE DRAWINGS

Other and further objects, features and advantages of the invention will appear more fully from the following description. The accompanying drawings, which are incorporated in and constitute a part of the specification, illustrate preferred embodiments of the invention, and together with the general description given above and the detailed description given below, serve to explain the principles of the invention.

FIG. 1 is a schematic diagram depicting a cross sectional view of a thin film solar cell according to an exemplary embodiment of the invention;

FIG. 2 is a diagram illustrating the influence of sodium dopant to the light conversion efficiency of the thin film solar cell of FIG. 1.

### DETAILED DESCRIPTION OF THE INVENTION

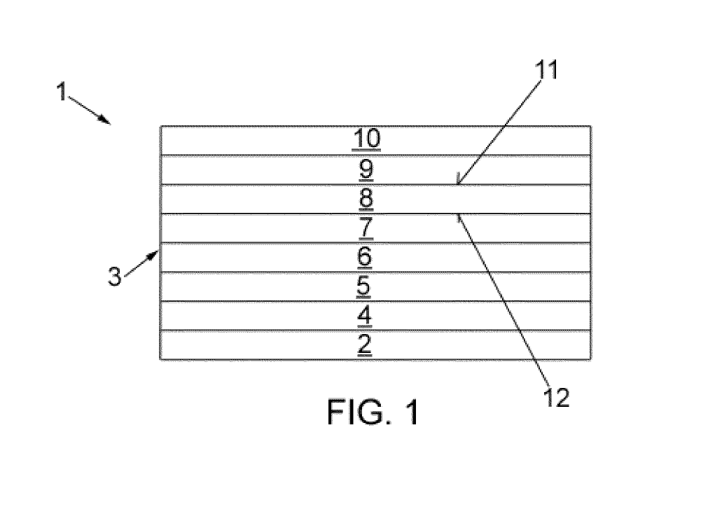

By way of illustration, specific embodiments in which the invention may be practiced now are described. Reference is first made to FIG. 1 depicting across sectional view of an encapsulated thin film solar cell according to an exemplary embodiment of the invention.

A thin film solar cell generally referred to at reference numeral 1 exhibits a laminated glass structure. Accordingly, it comprises a bottom-side substrate 2 made of electrically isolating material such as, but not limited to, an organic glass and plastics (polymers). Specifically, the substrate 2 can be configured as stiff plate or elastic foil according to the specific demands of the user. In the present embodiment, the substrate 2 is a stiff glass plate made of soda lime glass (SLG) having a comparably low light transmission. The substrate 2 may, e.g., have a thickness in a range of from 1 to 5 mm, especially 2 to 3 mm. In the present embodiment, the substrate 2 made of SLG has a thickness of 2.1 mm so as to provide sufficient stability and stiffness for handling the solar cell 1.

In the solar cell 1, the substrate 2 is provided with a layered stack 3 arranged at a light-entering side of the substrate 2 consisting of various layers stacked one upon the other. Specifically, the layered stack 3 includes a barrier layer 4 deposited on the substrate 2 and made of a material configured to inhibit the diffusion of alkaline metals, especially sodium (ions), such as, but not limited to, silicon nitride (Si₃N₄), silicon oxynitride (SiON), silicon oxycarbide SiOC, silicon carbonitride (SiCN) and aluminium oxide (Al₂O₃). Stated more particularly, the barrier layer 4 can, e.g., be adapted to reduce the diffusion of alkaline metals, especially sodium, to less than 1% compared to the case of having no barrier layer 4. The barrier layer 4 is deposited on the substrate 2 by means of a physical vapour deposition (PVD) technique such as, but not limited to, thermal evaporation and cathode sputtering. In the present embodiment, the barrier layer 4, e.g., has a layer thickness of 140 nm so as to at least approximately completely inhibit the diffusion of sodium ions.

The layered stack 3 further includes a back-electrode layer 5 deposited on the barrier layer 4 by means of a PVD-technique such as, but not limited to, thermal evaporation and cathode sputtering. The back-electrode layer 5 is made of an electrically conductive material, typically an opaque metal such as, but not limited to, molybdenum (Mo), aluminium (Al), copper (Cu), titanium (Ti) and multi-layer arrangengents comprising such metal, e.g., molybdenum (Mo). The back-electrode layer 5 may, e.g., have a layer thickness in a range of from 300 nm to 600 nm. In the present embodiment, the back-electrode layer 5 is made of Mo and has a layer thickness of 450 nm. The back-electrode layer 5 serves as back electrode of the solar cell 1.

With continued reference to FIG. 1, the layered stack 3 of the solar cell 1 further comprises a compound semiconductor 6 serving as light absorbing material or absorber of the solar cell 1 deposited on the back-electrode layer 5. Accordingly, the compound semiconductor 6 is being configured for converting light into electric energy such as, but not limited to, a sodium-doped compound semiconductor of the type Cu₂ZnSn(S,Se)₄. The diction “Cu₂ZnSn(S,Se)₄” means that the chalcogens sulphur (S) and selenium (Se) are in combination present in the compound semiconductor 6. The compound semiconductor 6 may, e.g., have a layer thickness in a range of from 0.5 to 5 μm. In the present embodiment, the compound semiconductor 6 consists of sodium-doped Cu₂ZnSn(S,Se)₄ and has a layer thickness of 1 to 2 μm.

In the solar cell 1, the compound semiconductor 6 is produced from precursor materials which by applying a thermal annealing process (RTP) are made to crystallize to the compound semiconductor. As already described in the introductory section, such method is well-known to those of skill in the art.

Specifically, in the solar cell 1, the precursor materials of the compound semiconductor 6 are deposited in a two-stage deposition process. Stated more particularly, in a first deposition stage, a first precursor layer (not illustrated) consisting of metals is deposited on the back electrode layer 5. In the present embodiment, in the first deposition stage, a first precursor layer containing the metals copper (Cu), zinc (Zn) and tin (Sn) is deposited on the back electrode layer 5. One or more of the following PVD-techniques can be used to deposit the precursor metals:
Sputtering of the precursor metals Cu, Zn, Sn from elemental targets containing these metals in elemental form;
Sputtering of the precursor metals Cu, Zn, Sn from binary or ternary alloy targets containing binary or ternary alloys of these metals, e.g., Cu—Sn, Cu—Zn, Zn—Sn or Cu—Zn—Sn and/or combinations thereof;
Thermal evaporation, electron beam evaporation and/or laser ablation of the precursor metals Cu, Zn, Sn from sources in which these metals are contained in elemental form (elemental sources);
Thermal evaporation, electron beam evaporation and/or laser ablation of the precursor metals Cu, Zn, Sn from sources in which binary or ternary alloys of these metals, e.g., Cu—Sn, Cu—Zn, Zn—Sn or Cu—Zn—Sn and/or combinations thereof, are contained.

Optionally, an additional deposition from elemental sources can used in order to specifically adapt the stoichiometry of the compound semiconductor.

Specifically, in case of depositing the precursor metals from elemental targets or elemental sources, the above-described first precursor layer consists of a sequence of single metallic layers, each of which consisting of one elemental metal, i.e., one of the metals Cu, Zn or Sn. For example, the first precursor layer consists of three single layers, e.g., deposited in the following sequence Cu/Zn/Sn. Those of skill in the art will appreciate that any other sequence of single layers can be envisaged according to the specific demands of the user. According to one preferred embodiment, a plurality of such sequences, each of which consisting of three single layers is repetitively (successively) deposited so that the first precursor layer consists of a stack of n similar or different sequences of single layers (e.g. n=2 to 20) wherein each sequence consists of three single metallic layers.

Otherwise, in case of depositing the precursor metals from alloy targets or alloy sources, the above-described first precursor layer consists of one or more single metallic layers, each of which consisting of a binary or ternary alloy of the metals Cu/Zn/Sn. In case of an additional deposition of the precursor metals from elemental targets or elemental sources, one or more of the single layers can contain elemental Cu, Zn or Sn. The single layers preferably are deposited in a pre-defined sequence, each of which consisting of a binary or ternary alloy of the metals Cu/Zn/Sn and (optionally) elemental Cu, Zn or Sn. According to one preferred embodiment, a plurality of such sequences is repetitively (successively) deposited so that the first precursor layer consists of a stack of n similar or different sequences of single metallic layers (e.g. n=2 to 20).

In a second deposition stage of the two-stage deposition process, a second precursor layer (not illustrated) containing at least one chalcogen is deposited on the first precursor layer. In the present embodiment, in the second deposition stage, a second precursor layer containing sulphur (S) and/or selenium (Se) is deposited on the first precursor layer. The one or more chalcogens are deposited without metals or binary or ternary metal alloys. When depositing sulphur (S) and/or selenium (Se), it is preferred that the substrate 2 has a temperature of less than 100° C. so as to prevent a partial reaction of the metals of the first precursor layer with the chalcogen(s).

One or more of the following PVD-techniques can be used to deposit the chalcogen(s):
Sputtering of the chalcogen(s) S and/or Se from elemental targets containing these chalcogens in elemental form;
Thermal evaporation of the chalcogen(s) S and/or Se from sources in which these metals are contained in elemental or combined form.

The first and second precursor layers commonly form a precursor layer stack. In one embodiment, such precursor stack is repetitively deposited (multiple sequence) which can be preferred in view of crystallization and/or sulphur depth profile in the compound semiconductor obtained.

Subsequently, the first and second precursor layers, i.e. the precursor layer stack, is thermal-processed (RTP) so as to reactively convert the metals Cu, Zn, Sn and S and/or Se to the pentanary compound semiconductor CZTSSe. Specifically, in one embodiment, while thermal-processing (annealing) the precursor materials, at least one process gas at least containing the remaining chalcogen (S or Se) to obtain the pentanary compound semiconductor CZTSSe is supplied to the layered stack 3. Specifically, sulphur and/or selenium and/or hydrogen sulfide (H₂S) and/or hydrogen selenide (H₂Se) or combinations thereof are supplied to the process area in controlled manner. Each process gas can be supplied during a pre-defined interval when thermal-processing the precursor materials wherein this interval can be shorter or equal to the period of annealing the precursor materials. Otherwise, the amount of process gas supplied per time unit can be constant or vary according to the specific demands of the user. In particular, the specific composition of the chalcogen-containing atmosphere during annealing of the precursor materials can be constant or vary according to the specific demands of the user.

Rapid thermal-processing of the precursor materials to crystallize the compound semiconductor usually requires:
quick heating-up rates in a range of some K/sec,
maximum temperatures above 400° C., preferably above 500° C.,
high homogeneity of the temperature of the substrate,
sufficiently high partial pressure(s) of the chalcogen(s) in the process gas(es) while thermal-processing the precursor materials,
controlled supply of the process gas(es).

The thermal-processing of the precursor materials preferably is carried out in a process box reducing the process space available for processing the precursor materials. Specifically, the partial pressure(s) of the chalcogen(s) can readily be kept constant using a process box. Since the use of a process box is known to those of skill in the art, e.g., from DE 102008022784 A1, it is not necessary to elucidate it further herein.

For producing the pentanary compound semiconductor CZTSSe, the thermal-processing of the precursor materials preferably is carried out under application of a controlled profile regarding the temperature of the substrate and composition and partial pressure(s) of the at least one process gas so as to obtain a (pre-)defined depth profile of the ratio S/(Se+S), i.e., the contents of sulphur (S) related to the summarized contents of sulphur and selenium (S+Se).

The term “sulphur depth profile” denotes the contents of sulphur (S) and the course of the ratio S/(Se+S), respectively, in the absorber 6 along a linear dimension of the absorber 6, starting from a first boundary face 11 towards a second boundary face 12 of the absorber 6 along the stacking direction of the layered stack 3.

According to a first variant, the thermal-processing is carried out in such a manner that the sulphur depth profile is continuously decreasing from the first boundary face 11 to the second boundary face 12 so that the sulphur depth profile is maximal at the first boundary face 11 and minimal at the second boundary face 12.

According to a second variant, the thermal-processing is carried out in such a manner that the sulphur depth profile is continuously increasing from the first boundary face 11 to the second boundary face 12 so that the sulphur depth profile is minimal at the first boundary face 11 and maximal at the second boundary face 12.

According to a third variant, the thermal-processing is carried out in such a manner that the sulphur depth profile is decreasing and then increasing so that the sulphur depth profile has a first maximum value at the first boundary face 11 to reach a minimum value in-between the first and second boundary faces 11, 12, to then have a second maximum value at the second boundary face 12.

According to a fourth variant, the thermal-processing is carried out in such a manner that the sulphur depth profile is increasing and then decreasing so that the sulphur depth profile has a first minimum value at the first boundary face 11 to reach a maximum value in-between the first and second boundary faces 11, 12, to then have a second minimum value at the second boundary face 12.

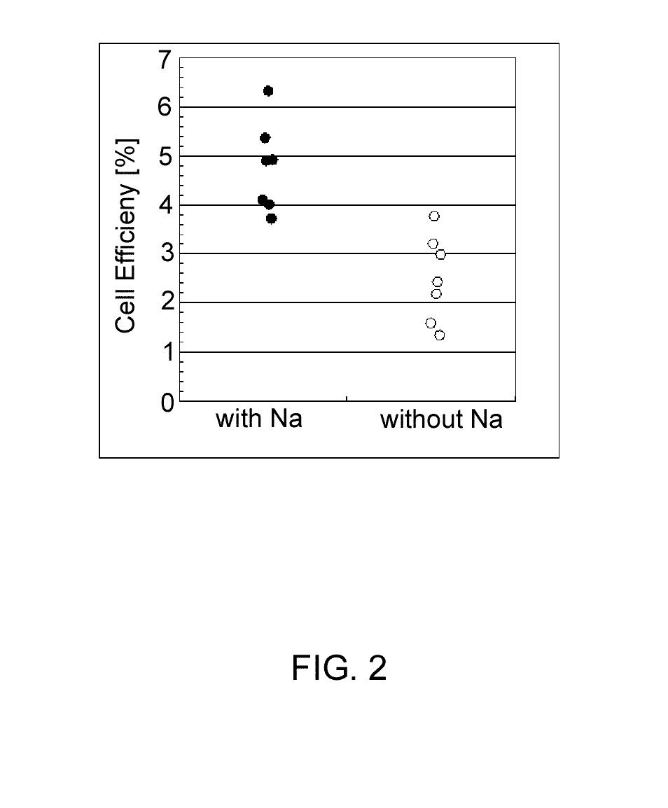

In the solar cell 1, the pentanary compound semiconductor CZTSSe of the absorber 6 is doped with sodium (Na). For this purpose, elemental sodium and/or a sodium-containing compound is supplied prior to and/or during and/or after thermal-processing of the precursor materials by a PVD-technique such as, but not limited to, thermal evaporation. By doping the compound semiconductor 6 the efficiency for converting light to electric energy can be strongly improved (see FIG. 2).

Stated more particularly, in one embodiment, gaseous sodium (Na) and/or a gaseous sodium-containing compound produced by thermal evaporation of one or more source materials is supplied during the rapid thermal-processing (RTP) of the precursor materials, i.e. during the annealing process, as a reaction gas. Source materials can, e.g., be sodium sulfide (Na₂S), sodium fluoride (NaF), Na-containing metal targets and others. Accordingly, gaseous sodium (Na) or the gaseous sodium-containing compound is transformed into the gas phase to then be condensed on the precursor materials crystallizing to the compound semiconductor of the type CZTSSe. The gaseous sodium (Na) and/or gaseous sodium-containing compound can be supplied during a pre-defined interval when thermal-processing the precursor materials wherein this interval can be shorter or equal to the period of thermal-processing the precursor materials. Otherwise, the amount of elemental sodium or sodium-containing compound in the process gas supplied per time unit can be constant or vary according to the specific demands of the user.

In one embodiment, elemental sodium and/or a sodium-containing compound is supplied after thermal-processing the precursor materials to crystallize the compound semiconductor 6. Generally, any PVD-technique can be used to deposit elemental sodium and/or a sodium-containing compound on the crystallized compound semiconductor after RTP such as, but not limited to, sputtering, thermal evaporation, electron beam evaporation and laser ablation. Source materials can, e.g., be sodium sulfide (Na₂S), sodium fluoride (NaF), Na-containing metal targets and others. A major advantage of this embodiment is given by the fact that crystallization of the compound semiconductor is not influenced by the dopant sodium (Na) so that any adverse effect of the dopant on the annealing process which could possibly arise can be avoided since the dopant is added after crystallization.

The post-RTP deposition of elemental sodium and/or a sodium-containing compound can be carried out on a hot or a cold substrate 2. Stated more particularly, elemental sodium and/or a sodium-containing compound can be deposited on a cold substrate 2 already cooled after the annealing process. In this case, a post-annealing heating step can be performed to chemically activate the dopant deposited on the compound semiconductor, e.g., by heating the substrate and layered stack 3 thereon to a temperature (e.g. <200° C.) that is lower than a temperature (e.g. >500° C.) for annealing the precursor materials for crystallizing the compound semiconductor.

Alternatively, elemental sodium and/or a sodium-containing compound can be deposited on a heated substrate 2 yet hot as a result of the thermal annealing process. Specifically, elemental sodium and/or a sodium-containing compound is deposited during the cool-down phase of the substrate 2 after the annealing process. In this case, a post-annealing heating step can be omitted since the chemical activation of the dopant deposited on the compound semiconductor can already be achieved by the hot substrate 2 so as to save time and costs in manufacturing the solar cell 1.

The post-RTP deposition of elemental sodium and/or a sodium-containing compound (after the annealing process) can also be combined with the deposition of elemental sodium and/or a sodium-containing compound during the thermal-processing of the precursor materials.

Furthermore, the post-RTP deposition of elemental sodium and/or a sodium-containing compound (after the annealing process) and/or the deposition of elemental sodium and/or a sodium-containing compound during the annealing process of the precursor materials can be combined with a deposition of elemental sodium and/or a sodium-containing compound prior to annealing the precursor materials as part of the (two-stage) deposition process for depositing of the precursor materials (metals and chalcogen(s)). Generally, any PVD-technique can be used to deposit elemental sodium and/or a sodium-containing compound prior to the RTP such as, but not limited to, sputtering, thermal evaporation, electron beam evaporation and laser ablation. Source materials can, e.g., be sodium sulfide (Na₂S), sodium fluoride (NaF), Na-containing metal targets and others. Elemental sodium and/or a sodium-containing compound can, e.g., be deposited on the back-elektrode layer 5, the first precursor layer containing the precursor metals and/or the second precursor layer containing the precursor chalcogen(s).

The deposition of elemental sodium and/or sodium-containing compound preferably is carried out in controlled manner so as to obtain a (pre-) defined depth profile of the ratio Na/(Cu+Zn+Sn), i.e., the contents of sodium (Na) related to the summarized contents of copper (Cu), zinc (Zn) and tin (Sn). The term “sodium depth profile” denotes the contents of sodium (Na) and the course of the ratio Na/(Cu+Zn+Sn), respectively, in the compound semiconductor 6 along a linear dimension of the compound semiconductor 6, starting from the first boundary face 11 towards the second boundary face 12 of the compound semiconductor 6 along the stacking direction of the layered stack 3.

According to a first variant, the Na-doping is carried out in such a manner that the sodium depth profile is continuously decreasing from the first boundary face 11 to the second boundary face 12 so that the sodium depth profile is maximal at the first boundary face 11 and minimal at the second boundary face 12.

According to a second variant, the Na-doping is carried out in such a manner that the sodium depth profile is continuously increasing from the first boundary face 11 to the second boundary face 12 so that the sodium depth profile is minimal at the first boundary face 11 and maximal at the second boundary face 12.

According to a third variant, the Na-doping is carried out in such a manner that the sodium depth profile is decreasing and then increasing so that the sodium depth profile has a first maximum value at the first boundary face 11 to reach a minimum value in-between the first and second boundary faces 11, 12, to then have a second maximum value at the second boundary face 12.

According to a fourth variant, the Na-doping is carried out in such a manner that the sodium depth profile is increasing and then decreasing so that the sodium depth profile has a first minimum value at the first boundary face 11 to reach a maximum value in-between the first and second boundary faces 11, 12, to then have a second minimum value at the second boundary face 12.

In the pentanary semiconductor CZTSSe described herein, a variation of the sulphur content over the depth of the semiconductor means a variation of the bandgap over thickness. It thus is possible to realize a bandgap thickness profile in the CZTSSe thin film by exchanging selenium and sulphur in CZTSSe. It is possible to combine any of the above-described variants of sodium depth profiles with any of the above-described sulphur depth profiles. This can be effectively used for optimizing the efficiency of the processed solar cell 1. Both the sulphur and the Na profile can be detected in the final product, for example by time-of-flight secondary ion mass spectroscopy.

In one embodiment, the method includes a step of depositing of elemental sodium and/or a sodium-containing compound on the back-electrode layer 5 and a step of depositing of elemental sodium and/or a sodium-containing compound on top of the compound semiconductor 6, e.g. in advance of the annealing of the precursor layers. As a result, the compound semiconductor 6 is produced in such a manner that the sodium content at the first boundary face 11 has a first maximum, decreases towards the second boundary face 12 to have a minimum, and increases towards the second boundary face 12 to have a second maximum at the second boundary face 12. This is combined with a sulphur depth profile in which the sulphur content at the first boundary face 11 has a first maximum, decreases towards the second boundary face 12 to have a minimum, and increases towards the second boundary face 12 to have a second maximum at the second boundary face 12. As a result, by producing the pentanary compound semiconductor in a two-stage process combined with the above-describe sulphur and sodium depth profiles, a solar cell 1 having an excellent light conversion efficiency can be produced.

The layered stack 3 of the solar cell 1 yet further includes at least one buffer layer 7 deposited on the compound semiconductor 6 by means of any PVD-technique such as, but not limited to, vacuum evaporation or cathode sputtering. The buffer layer 7, e.g., consists of CdS, InₓS_{y}, (In,Ga,Al)ₓ(S,Se)_{y}, ZnS, Zn(O,S), Zn(Mg,O), optionally in combination with intrinsic i-ZnO.

The layered stack 3 of the solar cell 1 yet further includes a front-electrode layer 8 deposited on the buffer layer 7 by means of any PVD-technique such as, but not limited to, vacuum evaporation or cathode sputtering. The front-electrode layer 8 is made of an electrically conductive material transparent for the light which is to be converted to electric energy by the compound semiconductor 6 (e.g. visible light). Typically, the front-electrode layer 8 consists of a metal oxide (TCO=Transparent Conductive Oxide) such as, but not limited to, aluminium (Al)-doped zincoxide (ZnO), boron (B)-doped zincoxide (ZnO), or gallium (Ga)-doped zincoxide (ZnO). The front-electrode layer 8 may, e.g., have a layer thickness in a range of from 300 to 1500 nm. In the present embodiment, the front-electrode layer 8 is made of TCO and has a layer thickness of 500 nm. The front-electrode layer 8 serves as a front electrode of the solar cell 1.

The front-electrode layer 8, buffer layer 7 and compound semiconductor 6 jointly form a heterojunction, i.e., a sequence of layers having opposite charge carriers. Specifically, the buffer layer 7 is used to electronically adapt the semiconducting material to the front-electrode layer 8.

In order to protect the layered stack 3 against environmental influences, in the solar cell 1, the substrate 2 is laminated with a cover plate 10, e.g., made of glass having a low content of ferrum (Fe) so as to be transparent for the light to be converted by the absorber 6 (e.g. solar light). The cover plate 10 or front glass may, e.g., have a thickness in a range of from 1 to 4 mm.

A lamination foil 9 deposited on the front-electrode layer 8 is used for laminating the substrate 2 and the cover plate 10. The lamination foil 9 consists of material adapted to thermally fix the substrate 2 and the cover plate 10 such as, but not limited to, polyvinylbutyral (PVB), ethylenevinylacetate (EVA) or DNP.

Reference is now made to FIG. 2 illustrating the influence of sodium dopant to the efficiency of the thin film solar cell 1 as described in connection with FIG. 1. Specifically, FIG. 2 depicts the cell efficiency [%] or light conversion efficiency of the solar cell 1 having an absorber 6 of the type Cu₂ZnSn(S,Se)₄ with or without sodium as dopant. Accordingly, a significant improvement of the cell efficiency up to about 6% can be attained by doping the compound semiconductor 6 with sodium. In this example, the mass fraction of sodium relative to the summarized mass fraction of copper, zinc and tin (Cu+Zn+Sn), amounts to about 0.1%. The summarized mass/area-ratio of copper, zinc and tin (Cu+Zn+Sn) amounts to about 0.6 mg/cm². A comparable result can be obtained by having a mass fraction of sodium relative to the summarized mass fraction of copper, zinc and tin (Cu+Zn+Sn), amounting to about 0.12%. Amass fraction of sodium relative to the summarized mass fraction of copper, zinc and tin (Cu+Zn+Sn), amounting to about 0.14% yielded an efficiency of 4.6%.

As above-detailed, the present invention proposes a new method of manufacturing solar cells having an improved efficiency for converting light to electric energy. Specifically, elemental sodium and/or a sodium-containing compound is supplied prior to and/or during and/or after the thermal annealing of the precursor materials.

Further features of the invention are disclosed by the following description:

A method for producing a layered stack for manufacturing thin film solar cells, comprising the following steps of: providing of a substrate; depositing of a barrier layer consisting of a material adapted to inhibit the diffusion of alkali metals on said substrate; depositing of an electrode layer on said barrier layer; depositing of precursor layers of a compound semiconductor on said electrode layer; annealing of said precursor layers to crystallize said compound semiconductor; depositing of elemental sodium and/or a sodium-containing compound (i) on said precursor layers and/or said electrode layer in advance of said annealing of said precursor layers, (ii) on said precursor layers during said annealing of said precursor layers, and/or (iii) on said compound semiconductor (6) after annealing of said precursor layers.

In one embodiment, said step of depositing of elemental sodium and/or a sodium-containing compound on said compound semiconductor after annealing said precursor layers is followed by a step of thermal-processing said compound semiconductor for chemically activating sodium as dopant in said compound semiconductor.

In one embodiment, thermal-processing said compound semiconductor is carried out by heating said compound semiconductor to a temperature lower than a temperature for annealing of said precursor layers to crystallize said compound semiconductor.

In one embodiment, elemental sodium and/or a sodium-containing compound is deposited on said compound semiconductor after annealing of said precursor layers wherein as a result of annealing of said precursor layers said compound semiconductor has a temperature sufficiently high for chemically activating sodium as dopant in said compound semiconductor.

In one embodiment, said compound semiconductor is produced in such a manner that one of the following sodium depth profiles between a first boundary face and a second boundary face of said compound semiconductor, said first boundary face being more distanced from said substrate than said second boundary face, is obtained: (i) a sodium content at said first boundary face is maximal and continuously decreases towards said second boundary face to be minimal at said second boundary face, (ii) a sodium content at said first boundary face is minimal and continously increases towards said second boundary face to be maximal at said second boundary face, (iii) a sodium content at said first boundary face has a first maximum, decreases towards said second boundary face to have a minimum, and increases towards said second boundary face to have a second maximum, (iv) a sodium content at said first boundary face has a first minimum, increases towards said second boundary face to have a maximum, and decreases towards said second boundary face to have a second minimum.

In one embodiment, the method is for manufacturing a thin film solar cell having a compound semiconductor of the type Cu₂ZnSn(S,Se)₄, wherein said step of depositing of said precursor layers comprises the following steps of: depositing of a first precursor layer comprising the metals copper, zinc and tin; depositing of a second precursor layer comprising at least one chalcogene selected from sulphur and selenium on said first precursor layer; supplying of at least one process gas during annealing of said first and second precursor layers, wherein (i) in case sulphur or selenium is contained in said second precursor layer, the other chalcogen and/or a compound containing the other chalcogen is contained in said process gas, or (ii) in case sulphur and selenium are contained in said second precursor layer, sulphur and/or selenium and/or a compound containing sulphur and/or a compound containing selenium is contained in said process gas.

In one embodiment, said compound semiconductor is produced in such a manner that a mass fraction of sodium in said compound semiconductor, relative to a mass fraction of the metals copper, zinc and tin contained in the compound semiconductor, is in a range of from 0.01% and 0.5%.

In one embodiment, said compound semiconductor is produced in such a manner that one of the following sulphur depth profiles between a first boundary face and a second boundary face of said compound semiconductor, said first boundary face being more distanced from said substrate than said second boundary face, is obtained: (i) a sulphur content at said first boundary face is maximal and continuously decreases towards said second boundary face to be minimal at said second boundary face, (ii) a sulphur content at said first boundary face is minimal and continously increases towards said second boundary face to be maximal at said second boundary face, (iii) a sulphur content at said first boundary face has a first maximum, decreases towards said second boundary face to have a minimum, and increases towards said second boundary face to have a second maximum, (iv) a sulphur content at said first boundary face has a first minimum, increases towards said second boundary face to have a maximum, and decreases towards said second boundary face to have a second minimum.

In one embodiment, said compound semiconductor is produced in such a manner that a relative change of sulphur content along said sulphur depth profile amounts to at least 10%.

In one embodiment, said compound semiconductor is produced in such a manner that said sulphur depth profile is specifically adapted to said sodium depth profile.

The above-described various embodiments of the method for producing a layered stack for manufacturing a thin film solar cell can be used alone or in any combination thereof without departing from the scope of the invention.

A method for manufacturing thin film solar cells according to the invention comprises the above-described method for producing a layered stack for manufacturing thin film solar cells.

While exemplary embodiments have been presented in the foregoing, it is to be understood that the embodiments are only examples, and are not intended to limit the scope, applicability, or configuration in any way. Obviously many modifications and variations of the present invention are possible in light of the above description. It is therefore to be understood, that within the scope of appended claims, the invention may be practiced otherwise than as specifically devised.

### REFERENCE LIST

1 Solar cell

2 Substrate

3 Layered stack

4 Barrier layer

5 Back-electrode layer

6 Compound semiconductor

7 Buffer layer

8 Front-electrode layer

9 Lamination foil

10 Cover plate

11 First boundary face

12 Second boundary face

1. A method for producing a layered stack for manufacturing a thin film solar cell having a compound semiconductor of the type Cu₂ZnSn(S,Se)₄, comprising the following steps of:
providing a substrate;
depositing a barrier layer consisting of a material adapted to inhibit the diffusion of alkali metals on said substrate;
depositing an electrode layer on said barrier layer;
depositing a first precursor layer comprising the metals copper, zinc and tin;
depositing a second precursor layer comprising at least one chalcogene selected from sulphur and selenium on said first precursor layer;
annealing said precursor layers to crystallize said compound semiconductor
supplying at least one process gas during annealing of said first and second precursor layers, wherein
(i) in case sulphur or selenium is contained in said second precursor layer, the other chalcogen and/or a compound containing the other chalcogen is contained in said process gas, or
(ii) in case sulphur and selenium are contained in said second precursor layer, sulphur and/or selenium and/or a compound containing sulphur and/or a compound containing selenium is contained in said process gas;
depositing of elemental sodium and/or a sodium-containing compound
(i) on said precursor layers and/or said electrode layer in advance of said annealing of said precursor layers,
(ii) on said precursor layers during said annealing of said precursor layers, and/or (iii) on said compound semiconductor after annealing of said precursor layers;
wherein said compound semiconductor is produced in such a manner that one of the following sodium depth profiles between a first boundary face and a second boundary face of said compound semiconductor, said first boundary face being more distanced from said substrate than said second boundary face, is obtained:
(i) a sodium content at said first boundary face (11) is maximal and continuously decreases towards said second boundary face to be minimal at said second boundary face,
(ii) a sodium content at said first boundary face is minimal and continuously increases towards said second boundary face to be maximal at said second boundary face,
(iii) a sodium content at said first boundary face has a first maximum, decreases towards said second boundary face to have a minimum, and increases towards said second boundary face to have a second maximum, or
(iv) a sodium content at said first boundary face has a first minimum, increases towards said second boundary face to have a maximum, and decreases towards said second boundary face to have a second minimum;
and wherein said compound semiconductor is produced in such a manner that one of the following sulphur depth profiles between said first boundary face and said second boundary face of said compound semiconductor is obtained:
(i) a sulphur content at said first boundary face is maximal and continuously decreases towards said second boundary face to be minimal at said second boundary face,
(ii) a sulphur content at said first boundary face is minimal and continuously increases towards said second boundary face to be maximal at said second boundary face,
(iii) a sulphur content at said first boundary face has a first maximum, decreases towards said second boundary face to have a minimum, and increases towards said second boundary face to have a second maximum, or
(iv) a sulphur content at said first boundary face has a first minimum, increases towards said second boundary face to have a maximum, and decreases towards said second boundary face to have a second minimum.

2. The method according to claim 1, wherein said step of depositing of elemental sodium and/or a sodium-containing compound on said compound semiconductor after annealing said precursor layers is followed by a step of thermal processing said compound semiconductor for chemically activating sodium as dopant in said compound semiconductor.

3. The method according to claim 2, wherein thermal processing of said compound semiconductor for chemically activating sodium as dopant in said compound semiconductor is carried out by heating said compound semiconductor to a temperature lower than a temperature for annealing of said precursor layers to crystallize said compound semiconductor.

4. The method according to claim 3, wherein said compound semiconductor is heated to a temperature in a range of from 100° C. to 400° C., particularly in a range of from 100° C. to 300° C., more particularly in a range of from 100° C. to 200° C., for chemically activating sodium as dopant in said compound semiconductor.

5. The method according to claim 1, wherein elemental sodium and/or a sodium-containing compound is deposited on said compound semiconductor after annealing of said precursor layers wherein as a result of annealing of said precursor layers said compound semiconductor has a temperature sufficiently high for chemically activating sodium as dopant in said compound semiconductor.

6. The method according to claim 5, wherein when starting deposition of sodium and/or sodium-containing compound, said compound semiconductor has a temperature in a range of from 100° C. to 400° C., particularly in a range of from 100° C. to 300° C., more particularly in a range of from 100° C. to 200° C.

7. The method according to claim 1, wherein gaseous sodium and/or a gaseous sodium-containing compound is produced by thermal evaporation of one or more source materials and is supplied during annealing of said precursor layers as a reaction gas.

8. The method according to claim 1, wherein said compound semiconductor is produced in such a manner that a mass fraction of sodium in said compound semiconductor, relative to a mass fraction of the metals copper, zinc and tin contained in the compound semiconductor, is in a range of from 0.01% and 0.5%.

9. The method according to claim 1, wherein said compound semiconductor is produced in such a manner that a relative change of sulphur content along said sulphur depth profile amounts to at least 10%.

10. The method according to claim 1, wherein said compound semiconductor is produced in such a manner that said sulphur depth profile is specifically adapted to said sodium depth profile.

11. The method according to claim 10, wherein said compound semiconductor is produced in such a manner that:
the following sodium depth profile is obtained: a sodium content at said first boundary face has a first maximum, decreases towards said second boundary face to have a minimum, and increases towards said second boundary face to have a second maximum, and that
the following sulphur depth profile is obtained: a sulphur content at said first boundary face has a first maximum, decreases towards said second boundary face to have a minimum, and increases towards said second boundary face to have a second maximum.

12. The method according to claim 1, comprising a step of depositing of elemental sodium and/or a sodium-containing compound on said electrode layer and a step of depositing of elemental sodium and/or a sodium-containing compound on said precursor layers.

13. A method for manufacturing a thin film solar cell comprising the method according to claim 1.
